(19) United States
(12) Patent Application Publication
(10) Pub. No.: US 2016/0291396 A1
(43) Pub. Date: Oct. 6, 2016

(54) LCD PANEL AND MANUFACTURING METHOD THEREOF

(71) Applicant: Chang XIE, Shenzhen, Guangdong (CN)

(72) Inventor: Chang XIE, Shenzhen, Guangdong (CN)

(21) Appl. No.: 14/652,791

(22) PCT Filed: Apr. 3, 2015
(86) PCT No.: PCT/CN2015/075827

§ 371 Date: Jun. 17, 2015

(51) Int. Cl. G02F 1/1333; G02F 1/1368; G02F 1/1339; H01L 27/12; G02F 1/1341; G02F 1/1343; H01L 29/66; G02F 1/1335; G02F 1/1337

(52) U.S. Cl. CPC G02F 1/133382; G02F 1/133514; G02F 1/1368; G02F 1/1339; G02F 1/133753; G02F 1/1341; G02F 1/13439; G02F 1/133516; H01L 29/66742; H01L 27/1259; G02F 2001/133761

(57) ABSTRACT

A liquid crystal display panel and a manufacturing method thereof are provided, the liquid crystal display panel includes: a color film substrate for providing color filter area; an array substrate having thin film transistors disposed thereon; alignment films disposed on the color film substrate and the array substrate, respectively; a liquid crystal layer comprising multiple layers of liquid crystal molecules; a heating layer disposed between the alignment film and the color film substrate, for heating the liquid crystal layer. The liquid crystal display panel and a manufacturing method avoid the liquid crystal molecules too viscosity to twist at low temperatures, and improve the response time.

### BACKGROUND OF THE INVENTION

1. Field of the Invention

The present invention relates to a field of LCD (Liquid Crystal Display) panels, and more specifically to an LCD panel and manufacturing method thereof.

2. Description of the Prior Art

In the image display field, the response time of LCD panel represents the response speed of each pixel to the inputting signal, that is, the time required for the pixel to turn from bright into dark or turn dark into bright. The response principle is to apply a voltage in the liquid crystal molecules in order to control turning on and off of the light by twisting and restoring of the liquid crystal molecules. The shorter the response time is, the less tracking the viewer feels when watching dynamic pictures.

The liquid crystal molecules will be thick in an environment under 0° C., and differences can be identified by the naked eye. When the temperature is lower, the liquid crystal molecules may even be crystallized. This leads to picture discoloration, blurring, and significant tracking when the liquid crystal display operates in a low temperature. Under extremely low temperatures (below 25° C)., the liquid crystal molecules may even fail to work normally.

As LCD panels become more widely used, outdoor display devices, such as advertising display screens on the exterior walls of buildings, military display screens, and display equipment used in field measurement are frequently subject to the failure situations.

### SUMMARY OF THE INVENTION

To overcome the above-mentioned disadvantages, the present invention aims to provide an LCD panel and manufacturing method thereof which improve the response time of the LCD panel.

The technical scheme of the present invention is illustrated hereunder.

An LCD panel, comprises:
a color film substrate for providing a color filter area;
an array substrate having thin film transistors disposed thereon;
alignment films disposed on the color film substrate and the array substrate, respectively;
a liquid crystal layer comprising multiple layers of liquid crystal molecules;
a heating layer disposed between the alignment film and the color film substrate, for heating the liquid crystal layer, wherein one edge of the heating layer is provided with an inputting electrode, and an opposite edge of the heating layer is provided with an outputting electrode, for transmitting a heating current;
a control switch for controlling turning on and off of the heating current of the heating layer;
a temperature sensor for receiving a current temperature; and
a comparator circuit for comparing the current temperature with a preset temperature, and turning on the heating current in the heating layer by controlling the control switch to be closed when the current temperature is lower than the preset temperature.

Preferably, the heating layer is formed by carbon nanotube films.

Preferably, the liquid crystal display further comprises:
a sealant for assembling the color film substrate with the array substrate;
a first conductive metal ball fixed by the sealant, and connecting the thin film transistors to the inputting electrode of the heating layer; and
a second conductive metal ball fixed by the sealant, and connecting the thin film transistors to the outputting electrode of the heating layer.

Preferably, the liquid crystal molecules in the liquid crystal layer are arranged in a symmetrical curved column structure, middle layers of the liquid crystal molecules are always perpendicular to the color film substrate, upper layers and lower layers are arranged in the symmetrical curved column structure, and the farther a column is away from the middle layer, the greater a pre-tilt angle of the column is.

The technical scheme of the present invention is illustrated hereunder.

An LCD panel comprises:
a color film substrate for providing color filter area;
an array substrate having thin film transistors disposed thereon;
alignment films disposed on the color film substrate and the array substrate, respectively;
a liquid crystal layer comprising multiple layers of liquid crystal molecules; and
a heating layer disposed between the alignment film and the color film substrate, for heating the liquid crystal layer.

Preferably, the heating layer is formed by carbon nanotube films.

Preferably, one edge of the heating layer is provided with an inputting electrode, and an opposite edge of the heating layer is provided with an outputting electrode, for transmitting a heating current.

Preferably, the LCD panel further comprises:
a sealant for assembling the color film substrate with the array substrate;
a first conductive metal ball fixed by the sealant, and connecting the thin film transistors to the inputting electrode of the heating layer; and
a second conductive metal ball fixed by the sealant, and connecting the thin film transistors to the outputting electrode of the heating layer.

Preferably, the LCD panel further comprises:
a control switch for controlling turning on and off of the heating current of the heating layer.

Preferably, the LCD panel further comprises:
a temperature sensor for receiving current temperature; and
a comparator circuit for comparing the current temperature with a preset temperature, and turning on the heating current in the heating layer by controlling the control switch to be closed when the current temperature is lower than the preset temperature.

Preferably, the liquid crystal molecules in the liquid crystal layer are arranged in a symmetrical curved column structure, middle layers of the liquid crystal molecules are always perpendicular to the color film substrate, upper layers and lower layers are arranged in the symmetrical curved column structure, and the farther a column is away from the middle layer, the greater a pre-tilt angle of the column is.

The technical schemes for providing a manufacturing method for an LCD panel of the present invention are illustrated hereunder, and the manufacturing method comprises the following steps:
(S1) preparing a color film substrate, for providing color filter area;
(S2) disposing a heating layer on the color film substrate;
(S3) disposing an alignment film on the heating layer, and the color film substrate, the heating layer, and the alignment film form a first substrate;
(S4) preparing an array substrate, and the array substrate having thin film transistors disposed thereon;
(S5) disposing the alignment film on the array substrate, and the array substrate and the alignment film form a second substrate; and
(S6) assembling the first substrate with the second substrate, and injuring liquid crystal molecules to form a liquid crystal layer.

Preferably, the step (S2) further comprises:
providing with an inputting electrode on one edge of the heating layer; and
providing with an outputting electrode on the edge opposite the inputting electrode.

Preferably, the step (S6) further comprises:
setting a first conductive metal ball on the thin film transistors to connect the inputting electrode of the heating layer;
setting a second conductive metal ball on the thin film transistor to connect the outputting electrode of the heating layer; and
coating a sealant, for assembling the color film substrate with the array substrate, while fixing the first conductive metal ball and the second conductive metal ball.

Compare to the prior art, the LCD panel and manufacturing method thereof in the present invention avoids the liquid crystal molecules too viscosity to twist at low temperatures, and significantly improves the response time of the LCD panel according to the design of a heating layer.

### BRIEF DESCRIPTION OF THE DRAWINGS

In order to describe the technical scheme in the implementation more clearly, the drawings bellow will be introduced in brief. The drawings in the description are just some of the embodiments, for a person of ordinary skill in the art, it is easy to acquire other drawings based on the following drawings without any creative labor.

FIG. 1 is a schematic diagram showing an LCD panel according to a first embodiment of the present invention;

FIG. 2A is a distribution diagram showing liquid crystal molecules in a power off situation according to the first embodiment of the present invention;

FIG. 2B is a distribution diagram showing liquid crystal molecules in a power on situation according to the first embodiment of the present invention;

FIG. 3 is a schematic diagram showing an LCD panel according to a second embodiment of the present invention; and

FIG. 4 is a flow chart of a manufacturing method for an LCD panel according to a third embodiment of the present invention.

### DETAILED DESCRIPTION OF THE PREFERRED EMBODIMENTS

Please refer to the drawings, in which the same component symbols represent the same components. The following description is based on the specific illustrated embodiments of the present invention, which should not be constructed as limitations to the present invention.

### Embodiment One

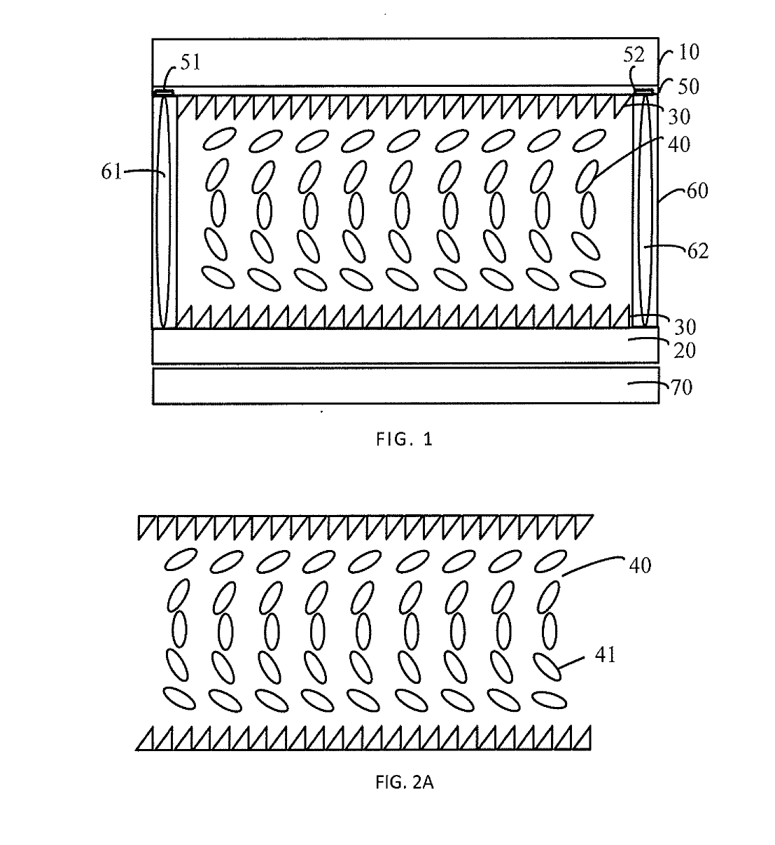

Please refer to FIG. 1, which shows a schematic diagram of an LCD panel according to a preferred embodiment of a present invention.

The LCD panel mainly comprises: a color film substrate 10, an array substrate 20, alignment films 30, a liquid crystal layer 40, a heating layer 50, a sealant 60, and a back light module 70.

Generally, the color film substrate 20 is used for providing color filter area (not shown).

The alignment films 30 are disposed on the color film substrate 10 and the array substrate 20, respectively.

The liquid crystal layer 40 comprises multiple layers of liquid crystal molecules. The liquid crystal molecules in the liquid crystal layer are arranged in a symmetrical curved column structure to implement a compensated angle, middle layers of the liquid crystal molecules are always perpendicular to the color film substrate, upper layers and lower layers are arranged in the symmetrical curved column structure, and the farther a column is away from the middle layer, the greater a pre-tilt angle of the column is.

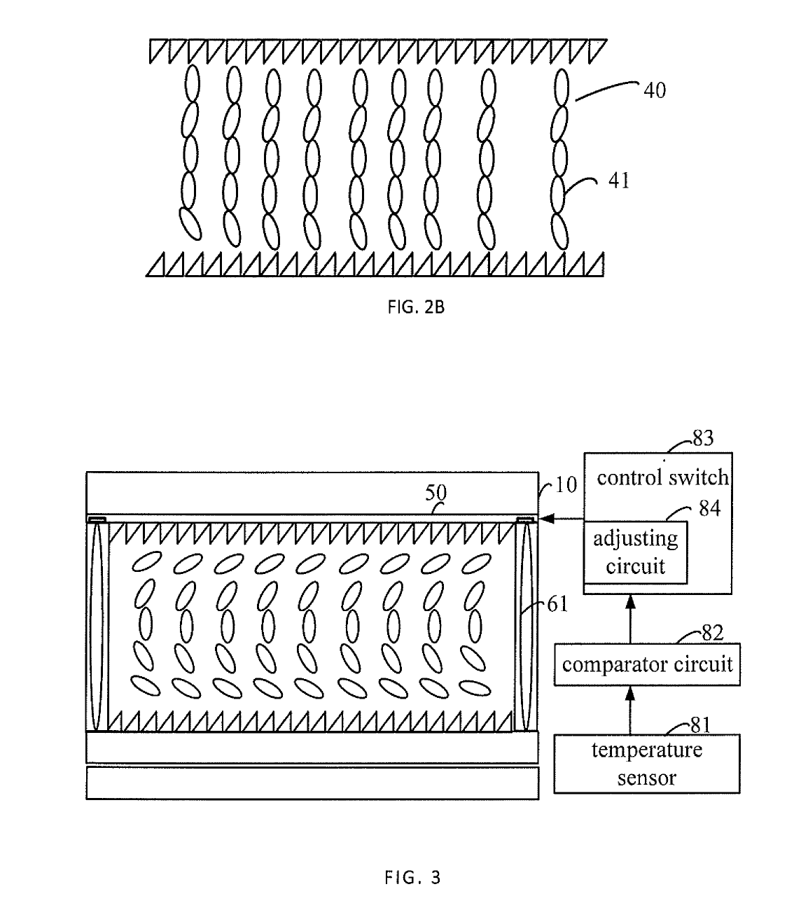

As shown in FIG. 2A and FIG. 2B, the distribution diagram of liquid crystal molecules in the power off situation and power on situation are provided. In the power off situation of FIG. 2A, the liquid crystal molecules 41 are arranged in a symmetrical curved column structure, the middle layer of the liquid crystal molecules 41 are always perpendicular to the display, the upper layers and the lower layers are arranged in the symmetrical curved column structure, and the farther a column is away from the middle layer, the greater a pre-tilt angle of the column is. In the power on situation of FIG. 2B, the liquid crystal molecules 41 turn to tilt, and finally get a symmetrical stack. The liquid crystal layer 40 is always symmetrical, a phase difference caused by birefringence of the lower liquid crystal molecules 41 offsets those of the upper liquid crystal molecules 41, and acquires a wide angle of view.

The heating layer 50 is disposed between the alignment film 30 and the color film substrate 10 for heating the liquid crystal layer 40.

It should be understood that the heating layer 50 is formed by carbon nanotube films, which have the advantage of good electrical conductivity and high thermal conductivity, and meet the demand of transparent display.

Furthermore, an inputting electrode 51 may be provided on one edge of the heating layer 50, and an outputting electrode 52 may be provided on the edge opposite to the inputting electrode 51, for transmitting a heating current. The heating current may be provided by the power circuit, or original electrical elements, such as TFTs on the array substrate 20. And the heating current is implemented by at least two conductive metal balls fixed by the sealant 60.

Generally, the first conductive metal ball 61 connects the TFTs (Thin Film Transistors) to the inputting electrode 51 of the heating layer; the second conductive metal ball 62 connects the TFTs to the outputting electrode 52 of the heating layer; the sealant 60 is used for assembling the color film substrate 10 with the array substrate 20.

The back light module 70 is disposed on one side of the array substrate 20, for providing lights for the LCD panel.

The LCD panel provided in the preferred embodiment of the present invention, avoids the liquid crystal molecules too viscosity to twist at low temperatures, and significantly improves the response time of the LCD panel according to the design a heating layer on the color film substrate. And the design of the heating layer is simply processed and has a low cost in materials and preparation.

### Embodiment Two

Please refer to FIG. 3, which shows another schematic diagram of an LCD panel according to a preferred embodiment of a present invention.

The difference between the second embodiment and the first embodiment is the addition of a temperature sense function, beyond the heating layer 50 on the color film substrate 10, for starting the heating function in a proper situation.

Generally, the LCD panel further comprises: a control switch 83, a temperature sensor 81, and a comparator circuit 82.

The control switch 83 is used for controlling turning on and off of the heating current of the heating layer. The control switch may be connected to a portion of the heating layer 50, the conductive metal ball 61, or the TFT (not shown).

The temperature sensor 81 is used for receiving a current temperature.

The comparator circuit 82 is used for comparing the current temperature with a preset temperature, and turning on the heating current in the heating layer by controlling the control switch 83 to be closed when the current temperature is lower than the preset temperature.

It should be understood that the control switch 83 further comprises an adjusting circuit 84, for connecting to different resistors according to the comparator circuit 82, so as to output different current values in the conduction situation. Therefore, the temperature output by the heating layer 50 will be controlled, and a proper temperature will be provided.

The LCD panel provided in the preferred embodiment of the present invention avoids the liquid crystal molecules too viscosity to twist at low temperatures, and significantly improves the response time of the LCD panel according to the design of a heating layer on the color film substrate. And the design of the heating layer is simply processed and has a low cost in materials and preparation.

### Embodiment Three

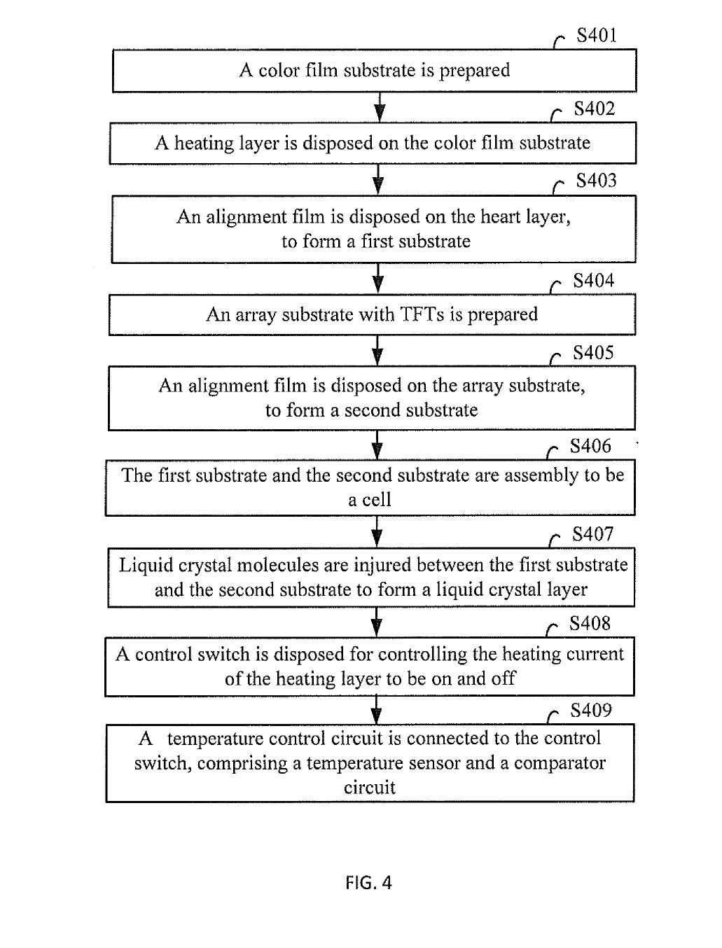

Please refer to FIG. 4, which shows a flow chart of a manufacturing method for LCD panel according to a preferred embodiment of the present invention. Generally, it comprises the following steps:

In Step S401, preparing a color film substrate for providing color filter area.

In Step S402, disposing a heating layer on the color film substrate.

It should be understood that an inputting electrode is provided on one edge of the heating layer, and an outputting electrode is provided on the edge opposite to the inputting electrode, after been disposed.

In Step S403, disposing an alignment film on the heating layer.

It should be understood that, after the Steps S401 to S403, the color film substrate, the heating layer, and the alignment film form a first substrate.

In Step S404, preparing an array substrate, and the array substrate has TFTs disposed thereon.

In Step S405, disposing another alignment film on the array substrate.

It should be understood that, after the Steps S404 to S405, the array substrate and the alignment film form a second substrate. It should be understood that the first substrate and the second substrate may be prepared at the same time.

In Step S406, assembling the first substrate with the second substrate to be a cell.

It should be understood that, the assembly process further comprises the following steps:
(1) Setting a first conductive metal ball for connecting the TFT to the inputting electrode of the heating layer;
(2) Setting a second conductive metal ball for connecting the TFT to the outputting electrode of the heating layer;
(3) Coating a sealant for assembling the color film substrate with the array substrate, while fixing the first conductive metal ball and the second conductive metal ball.

In Step S407, injuring liquid crystal molecules to form a liquid crystal layer.

In Step S408, setting a control switch for controlling turning on and off of the heating current of the heating layer.

In Step S409, connecting a temperature control circuit to the control switch. The temperature control circuit comprises a temperature sensor and a comparator circuit.

The temperature sensor is used for receiving a current temperature. The comparator circuit is used for comparing the current temperature with a preset temperature, and turning on the heating current in the heating layer by controlling the control switch to be closed when the current temperature is lower than the preset temperature.

It should be understood that the control switch further comprises an adjusting circuit for connecting to different resistors according to the comparator circuit, so as to output different current values in conduction situation. Therefore, the temperature output by the heating layer will be controlled, and a proper temperature will be provided.

The LCD panel provided in the preferred embodiment of the present invention avoids the liquid crystal molecules too viscosity to twist at low temperatures, and significantly improves the response time of the LCD panel according to the design of a heating layer on the color film substrate. The design of the heating layer is simply processed and has low cost in materials and preparation.

It should be understood that, although the embodiments have different concern, the design idea is consistent. Some ignored parts may relate to the whole specification, and are not repeated herein.

In conclusion, the present invention has been described with reference to certain preferred, and alternative embodiments which are intended to be exemplary only, and do not limit the full scope of the present invention as set forth in the appended claims.

What is claimed is:

1. A liquid crystal display panel, comprising:
a color film substrate for providing a color filter area;
an array substrate having thin film transistors disposed thereon;
alignment films, disposed on the color film substrate and the array substrate, respectively;
a liquid crystal layer comprising multiple layers of liquid crystal molecules;
a heating layer disposed between the alignment film and the color film substrate, for heating the liquid crystal layer, wherein one edge of the heating layer is provided with an inputting electrode, and an opposite edge of the heating layer is provided with an outputting electrode, for transmitting a heating current;
a control switch for controlling turning on and off of the heating current of the heating layer;
a temperature sensor for receiving a current temperature; and
a comparator circuit for comparing the current temperature with a preset temperature, and turning on the heating current in the heating layer by controlling the control switch to be closed when the current temperature is lower than the preset temperature.

2. The liquid crystal display panel as claimed in claim 1, wherein the heating layer is formed by carbon nanotube films.

3. The liquid crystal display panel as claimed in claim 1, further comprising:
a sealant for assembling the color film substrate with the array substrate;
a first conductive metal ball fixed by the sealant, and connecting the thin film transistor to the inputting electrode of the heating layer; and
a second conductive metal ball fixed by the sealant, and connecting the thin film transistor to the outputting electrode of the heating layer.

4. The liquid crystal display panel as claimed in claim 1, wherein the liquid crystal molecules in the liquid crystal layer are arranged in a symmetrical curved column structure, middle layers of the liquid crystal molecules are always perpendicular to the color film substrate, upper layers and lower layers are arranged in the symmetrical curved column structure, and the farther a column is away from the middle layer, the greater a pre-tilt angle of the column is.

5. A liquid crystal display panel, comprising:
a color film substrate for providing a color filter area;
an array substrate having thin film transistors disposed thereon;
an alignment film for disposing on the color film substrate and the array substrate, respectively;
a liquid crystal layer comprising multiple layers of liquid crystal molecules; and
a heating layer disposed between the alignment film and the color film substrate, for heating the liquid crystal layer.

6. The liquid crystal display panel as claimed in claim 5, wherein the heating layer is formed by carbon nanotube films.

7. The liquid crystal display panel as claimed in claim 5, wherein one edge of the heating layer is provided with an inputting electrode, and an opposite edge of the heating layer is provided with an outputting electrode, for transmitting a heating current.

8. The liquid crystal display panel as claimed in claim 7, wherein the liquid crystal display panel further comprises:
a sealant for assembling the color film substrate with the array substrate;
a first conductive metal ball fixed by the sealant, and connected the thin film transistors to the inputting electrode of the heating layer; and
a second conductive metal ball fixed by the sealant, and connecting the thin film transistors to the outputting electrode of the heating layer.

9. The liquid crystal display panel as claimed in claim 5, wherein the liquid crystal panel further comprises:
a control switch for controlling turning on and off of the heating current of the heating layer.

10. The liquid crystal display panel as claimed in claim 9, wherein the liquid crystal panel further comprises:
a temperature sensor for receiving a current temperature; and
a comparator circuit for comparing the current temperature with a preset temperature, and turning on the heating current in the heating layer by controlling the control switch to be closed when the current temperature is lower than the preset temperature.

11. The liquid crystal display panel as claimed in claim 5, wherein the liquid crystal molecules in the liquid crystal layer are arranged in a symmetrical curved column structure, middle layers of the liquid crystal molecules are always perpendicular to the color film substrate, upper layers and lower layers are arranged in the symmetrical curved column structure, and the farther a column is away from the middle layer, the greater a pre-tilt angle of the column is.

12. A manufacturing method for liquid crystal display panel, wherein the manufacturing method comprises the following steps:
(S1) preparing a color film substrate, for providing color filter area;
(S2) disposing a heating layer on the color film substrate;
(S3) disposing an alignment film on the heating layer, and the color film substrate, the heating layer, and the alignment film form a first substrate;
(S4) preparing an array substrate, and the array substrate having thin film transistors disposed thereon;
(S5) disposing the alignment film on the array substrate, and the array substrate and the alignment film form a second substrate; and
(S6) assembling the first substrate with the second substrate, and injuring multiple layers of liquid crystal molecules to form a liquid crystal layer.

13. The manufacturing method as claimed in claim 12, wherein the step (S2) further comprises:
setting an inputting electrode on one edge of the heating layer; and
setting an outputting electrode on the edge opposite to the inputting electrode.

14. The manufacturing method as claimed in claim 13, wherein the step (S6) further comprises:
setting a first conductive metal ball on the thin film transistors to connect the inputting electrode of the heating layer;
setting a second conductive metal ball on the thin film transistors to connect the outputting electrode of the heating layer; and
coating a sealant, for assembling the color film substrate with the array substrate, while fixing the first conductive metal ball and the second conductive metal ball.
